(19) United States
(12) Patent Application Publication
(10) Pub. No.: US 2009/0090409 A1
(43) Pub. Date: Apr. 9, 2009

(54) System and Method for Assembling a Microthermoelectric Device

(75) Inventor: Joshua E. Moczygemba, Wylie, TX (US)

Correspondence Address: BAKER BOTTS L.L.P., 2001 ROSS AVENUE, SUITE 600, DALLAS, TX, 75201-2980, US

(73) Assignee: Marlow Industries, Inc., Dallas, TX (US)

(21) Appl. No.: 12/239,077

(22) Filed: Sep. 26, 2008

Related U.S. Application Data
(60) Provisional application No. 60/977,845, filed on Oct. 5, 2007.

(51) Int. Cl. H01L 35/34

(52) U.S. Cl. 136/201

(57) ABSTRACT

A method for creating an array of thermoelectric elements may include providing a rigid block including P-type material layers and N-type material layers stacked in an alternating relationship and bonded together by an adhesive. First channels may be formed in the block parallel to the P-type material layers and the N-type material layers and may partially extend through a depth of the block leaving an uncut bottom on the block. The first channels may be filled with an electrically and thermally insulating material and second channels may be formed in the block, transverse to the first channels. The second channels may partially extend through the depth of the block. The second channels may be filled with the electrically and thermally insulating material and the uncut bottom may be removed from the block.

### CROSS REFERENCE TO RELATED APPLICATIONS

This application claims the benefit under 35 U.S.C. § 119(e) of U.S. Provisional Application No. 60/977,845, entitled “System and Method of Manufacturing a Microthermoelectric Device,” filed Oct. 5, 2007.

### TECHNICAL FIELD

The present disclosure relates to thermoelectric devices and more particularly, to a system and method of manufacturing a microthermoelectric device.

### BACKGROUND

The basic theory and operation of thermoelectric devices has been developed for many years. Presently available thermoelectric devices used for cooling typically include an array of thermocouples which operate in accordance with the Peltier effect. Thermoelectric devices may also be used for heating, power generation and temperature sensing.

Thermoelectric devices may be described as essentially small heat pumps which follow the laws of thermodynamics in the same manner as mechanical heat pumps, refrigerators, or any other apparatus used to transfer heat energy. A principal difference is that thermoelectric devices function with solid state electrical components (thermoelectric elements or thermocouples) as compared to more traditional mechanical/fluid heating and cooling components. The efficiency of a thermoelectric device is generally limited to its associated Carnot cycle efficiency reduced by a factor which is dependent upon the thermoelectric figure of merit (ZT) of the materials used in fabrication of the associated thermoelectric elements. Materials used to fabricate other components such as electrical connections, hot plates, and cold plates may also affect the overall efficiency of the resulting thermoelectric device.

Thermoelectric materials such as alloys of Bi₂Te₃, PbTe and BiSb were developed thirty to forty years ago. More recently, semiconductor alloys such as SiGe have been used in the fabrication of thermoelectric devices. Typically, a thermoelectric device incorporates both P-type and N-type semiconductor alloys as the thermoelectric materials.

In accordance with one method for the manufacture of a thermoelectric device, a billet of P-type material may be extruded to form a P-type ingot. Similarly, a billet of N-type material may be extruded to form an N-type billet. In particular embodiments, P-type and N-type billets may be plastically deformed or hot pressed. The P-type and N-type ingots are sliced into wafers, the wafers are diced into individual elements, and the elements are mechanically loaded into a grid or “matrix” with the desired pattern and assembled upon a plate. P-type and N-type elements are typically arranged into rectangular arrays, in order to form a thermoelectric device. P-type and N-type legs alternate in both array directions. A metallization may be applied to the P-type wafers, N-type wafers, and/or the plate, in order to arrange the P-type wafers and the N-type wafers electrically in series and thermally in parallel.

For many thermoelectric devices manufactured using this technique, the element dimensions may be approximately 0.6 mm by 1.0 mm. Generally, the legs have a square cross-section perpendicular to the direction of current flow. Commonly, there are 18 to 36 pairs of P-type and N-type elements in a thermoelectric device manufactured using this technique. Due to the size of the P-type and N-type elements, the elements are typically separated by hand, by using bowl sorters with pick and place automation, by using mass loading vibratory techniques, or any combination of the three, for installation upon the plate according to a predetermined generally alternating pattern. This method is time-consuming and intricate, and requires specialized equipment and experienced operators.

### SUMMARY

In particular embodiments, a method for creating an array of thermoelectric elements may include providing a rigid block including P-type material layers and N-type material layers stacked in an alternating relationship and bonded together by an adhesive. First channels may be formed in the block parallel to the P-type material layers and the N-type material layers and may partially extend through a depth of the block leaving an uncut bottom on the block. The first channels may be filled with an electrically and thermally insulating material and second channels may be formed in the block, transverse to the first channels. The second channels may partially extend through the depth of the block. The second channels may be filled with the electrically and thermally insulating material and the uncut bottom may be removed from the block.

In particular embodiments, the step of providing a rigid block including P-type material layers and N-type material layers may include providing P-type wafers and N-type wafers, applying adhesive to the P-type wafers and N-type wafers, and stacking the P-type wafers and N-type wafers in an alternating relationship. The P-type wafers and N-type wafers may be pressed together to decrease widths of the bond lines between the P-type wafers and N-type wafers and the adhesive may be cured to form a P/N-type ingot. The method may further include cutting the rigid block from the P/N-type ingot.

Technical advantages of the present disclosure may include creating a P/N-type array with element spacing precise enough to use photolithography or shadow mask techniques to create electrical interconnects between the elements in a production environment. Particular embodiments of the present disclosure may further minimize tolerance stack-up by employing slicing and dicing techniques to create uniform spacing between the thermoelectric elements in the array.

Other technical advantages of the present disclosure will be readily apparent to one skilled in the art from the following figures, descriptions, and claims. Moreover, while specific advantages have been enumerated above, various embodiments may include all, some, or none of the enumerated advantages.

### BRIEF DESCRIPTION OF THE DRAWINGS

For a more complete understanding of the present disclosure and its advantages, reference is now made to the following descriptions, taken in conjunction with the accompanying drawings, in which:

FIG. 1 illustrates an example thermoelectric device including an array of thermoelectric elements manufactured in accordance with an embodiment of the present disclosure;

FIG. 2 illustrates an isometric view of a P/N-type ingot created in accordance with an embodiment of the present disclosure;

FIG. 3 illustrates an isometric view of a P/N-type block created in accordance with an embodiment of the present disclosure;

FIG. 4 illustrates a series of channels and fins created in the P/N-type block of FIG. 3 according to an example embodiment of the present disclosure;

FIG. 5 illustrates a series of channels and fins created in the P/N-type block of FIG. 3 that have been backfilled with an electrically and thermally insulating adhesive according to an example embodiment of the present disclosure;

FIG. 6 illustrates a second series of channels and fins created in the P/N-type block of FIG. 3 according to an example embodiment of the present disclosure;

FIG. 7 illustrates a second series of channels and fins created in the P/N-type block of FIG. 3 that have been backfilled with an electrically and thermally insulating adhesive according to an example embodiment of the present disclosure;

FIG. 8 illustrates a portion of the P/N-type block of FIG. 3 being removed from a P/N-type array according to an example embodiment of the present disclosure;

FIG. 9 illustrates electrical interconnects that have been applied to the P/N-type array illustrated in FIG. 8 in accordance with an embodiment of the present disclosure; and

FIG. 10 illustrates example steps in a method for manufacturing the P/N-type array of FIG. 9 in accordance with an embodiment of the present disclosure.

### DETAILED DESCRIPTION OF EXAMPLE EMBODIMENTS

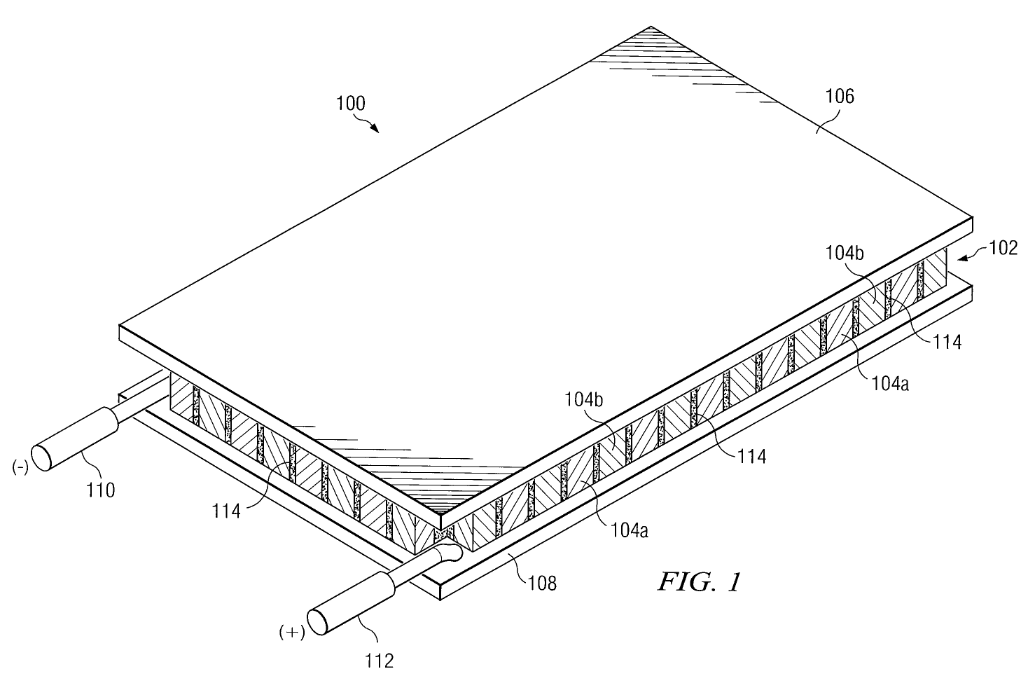

FIG. 1 illustrates an example thermoelectric device 100 including an array 102 of thermoelectric elements 104 disposed between a cold plate 106 and a hot plate 108. Electrical connections 110 and 112 may be provided to allow thermoelectric device 100 to be electrically coupled with an appropriate source of electrical power (e.g., a DC power source). Thermoelectric device 100 may be configure for use in any number of applications including but not limited to use as a heater, a cooler, an electrical power generator and/or a temperature sensor. For example, if thermoelectric device 100 were designed to function as an electrical power generator, electrical connections 110 and 112 would represent the output terminals from such a power generator operating between hot and cold temperature sources.

Array 102 may generally include a plurality of thermoelectric elements 104 fabricated from one or more dissimilar semiconductor materials such as N-type thermoelectric material and P-type thermoelectric material. Thermoelectric elements 104 are typically configured in a generally alternating N-type element to P-type element arrangement. For example, thermoelectric elements 104 may be arranged in alternating rows of N-type elements 104a and P-type elements 104b. In particular embodiments thermoelectric elements 104 may be bound together in array 102 by an electrically and thermally insulating material 114 disposed between each of the elements.

N-type semiconductor materials generally have more electrons than necessary to complete the associated crystal lattice structure. P-type semiconductor materials generally have fewer electrons than necessary to complete the associated crystal lattice structure. The “missing electrons” are sometimes referred to as “holes.” The extra electrons and extra holes are sometimes referred to as “carriers.” The extra electrons in N-type semiconductor materials and the extra holes in P-type semiconductor materials are the agents or carriers which transport or move heat energy between cold side or cold plate 106 and hot side or hot plate 108 through thermoelectric elements 104 when subject to a DC voltage potential. These same agents or carriers may generate electrical power when an appropriate temperature difference is applied to the cold side and hot side of array 102.

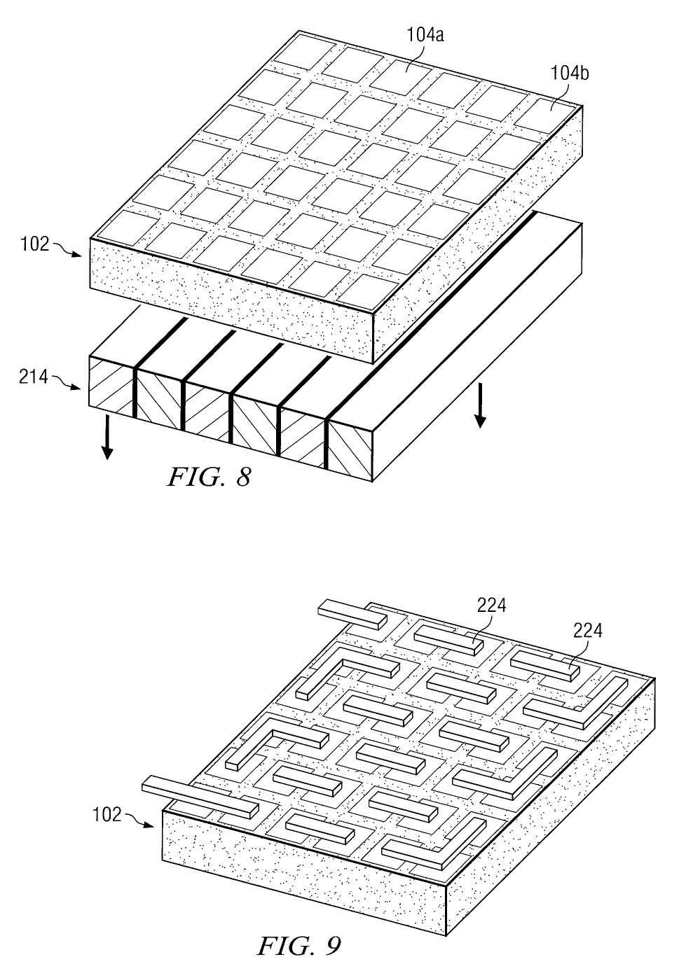

Plates 106 and 108 may be composed of any material suitable for acting as a substrate for array 102. As an example and not by way of limitation, plates 106 and 108 may be either rigid or flexible. Ceramic is a material commonly used to manufacture plates 106 and 108. In particular embodiments, a patterned metallization may be applied to one or both of plates 106 and 108 to electrically interconnect thermoelectric elements 104 when plates 106 and 108 are mounted to array 102; however, one of ordinary skill in the art will also appreciate that electrical interconnects 224 could also be applied directly on array 102 rather than on plates 106 or 108 as illustrated in the example embodiment of FIG. 9.

When electrical power from a power supply is properly applied to thermoelectric device 100, heat energy may be absorbed on cold side 106 of thermoelectric elements 104 and dissipated on hot side 108 of thermoelectric device 100. A heat sink or heat exchanger (sometimes referred to as a “hot sink”) may be attached to hot plate 108 of thermoelectric device 100 to aid in dissipating heat transferred by the associated carriers and phonons through thermoelectric elements 104 to the adjacent environment. In a similar manner, a “cold sink” may be attached to cold side 106 of thermoelectric device 100 to prevent heat from being transferred to the adjacent environment. Thus, thermoelectric device 100 may sometimes function as a thermoelectric cooler when properly connected with a power supply. However, since thermoelectric devices are a type of heat pump, thermoelectric device 100 may also have other applications such as use as a heater, power generator, or temperature sensor.

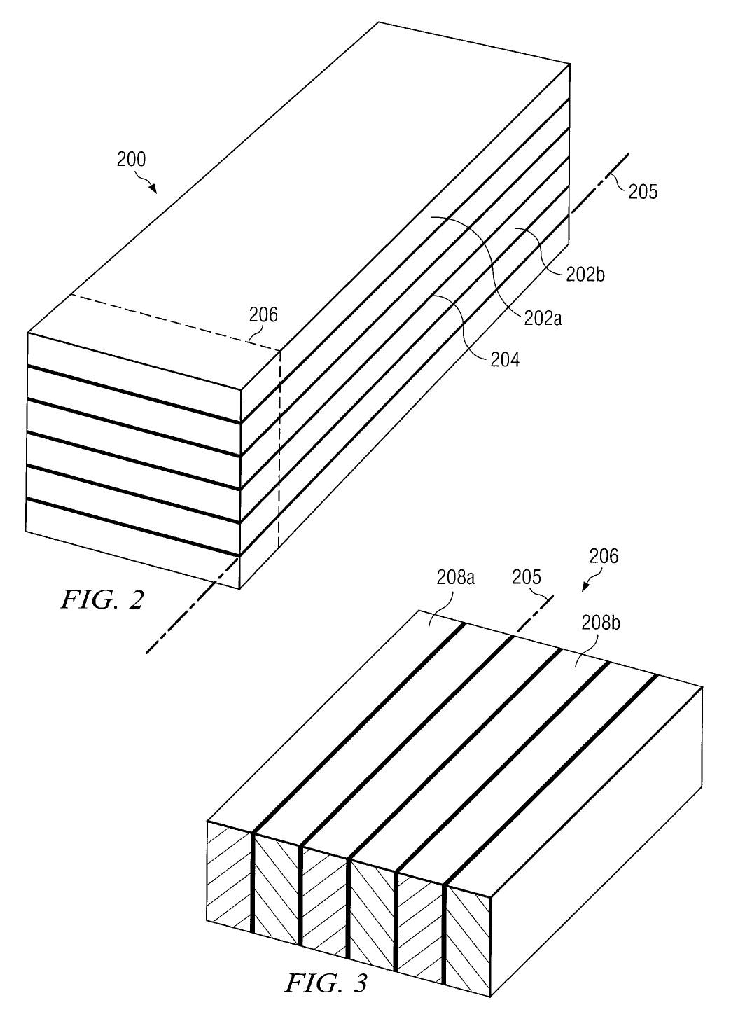

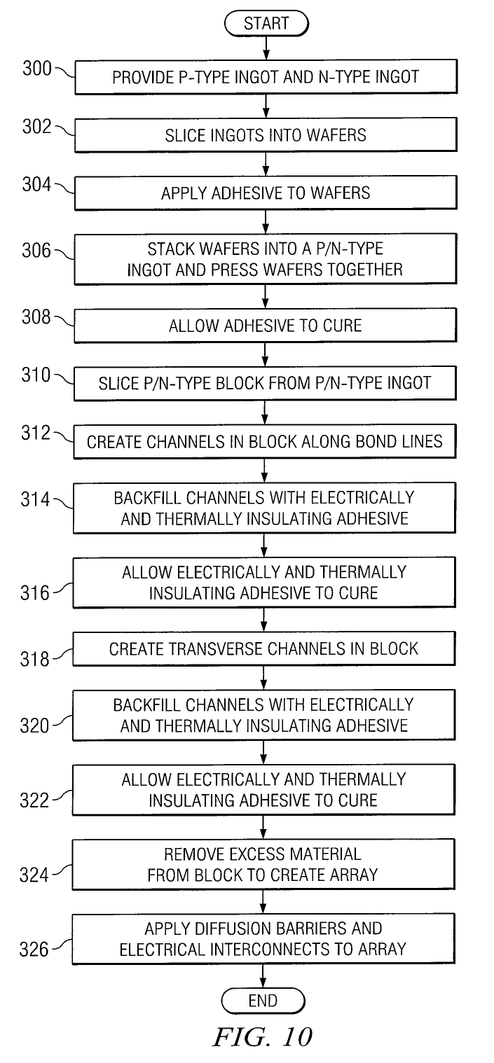

Although FIG. 1 illustrates array 102 being included as part of a stand-alone thermoelectric device 100, one of ordinary skill in the art will appreciate that the present disclosure contemplates the use of array 102 in any suitable thermoelectric unit for any suitable thermoelectric application. Such applications may include thermoelectric units having similar or different components than those described above with respect to thermoelectric device 100. One example embodiment of the process for forming array 102 is described in FIG. 10, example steps of which, are illustrated and described with respect to FIGS. 2-9.

FIG. 2 illustrates a P/N-type ingot 200 created as a preliminary step in one embodiment of the process of forming array 102. P/N-type ingot 200 includes a plurality of N-type wafers 202a and P-type wafers 202b that have been stacked in an alternating fashion and bonded together with an adhesive 204. N-type wafers 202a and P-type wafers 202b may be composed of any material suitable for use as a thermoelectric element 104. As an example and not by way of limitation, N-type wafers 202a and P-type wafers 202b may be composed of a semiconductor alloy such as Bismuth-telluride-based material (e.g., Bi₂Te₃₁).

In particular embodiments wafers 202 may be uniform in thickness or may differ in thickness and may be any shape or size. As an example and not by way of limitation, N-type wafers 202a and P-type wafers 202b may be rectangular in shape, each wafer 202 having two large, substantially flat faces, surrounded by four narrow edges. Typically, each wafer 202 included in P/N-type ingot 200 has approximately the same size and shape as every other wafer 202 in P/N-type block 206. One of ordinary skill in the art will appreciate that the above-described embodiments of N-type wafers 202a and P-type wafers 202b were presented for the sake of explanatory simplicity and will further appreciate that the present disclosure contemplates the use of any suitable number, composition, or configuration of P-type wafers 202b and N-type wafers 202a in P/N-type ingot 200.

In particular embodiments, the wafers 202 contained in P/N-type ingot 200 may be bound together by an adhesive 204. Adhesive 204 may be any compound capable of forming a rigid bond between the wafers 202 contained in P/N-type ingot 200. As an example and not by way of limitation, adhesive 204 may be Stycast W19, Stycast 1266, Loctite Hysol FP4531, super glue or other epoxy. One of ordinary skill in the art will appreciate that the above-described embodiments of adhesive 204 were presented for the sake of explanatory simplicity and will further appreciate that the present disclosure contemplates the use of any suitable adhesive 204 to form a rigid bond between the wafers 202 contained in P/N-type ingot 200.

In particular embodiments, to create P/N-type ingot 200, a plurality of N-type wafers 202a and P-type wafers 202b may be obtained and at least one face of each wafer 202 may be coated with adhesive 204. N-type wafers 202a and P-type wafers 202b may then be stacked in an alternating fashion and pressed together to reduce the amount of space between each adjacent wafer. Typically, when the wafers 202 are pressed together, the faces of each adjacent wafer 202 touch one another at particular locations along the bond line 205 (e.g., the area between the faces of the adjacent wafers 202). In particular embodiments, any excess adhesive 204 that is squeezed out of bond lines 205 when P/N-type ingot 200 is compressed may be removed (e.g., scraped away) before adhesive 204 cures (e.g., hardens). To compress P/N-type ingot 200, a clamp may be applied to the endmost wafers 202 in P/N-type ingot 200 and tightened; however, one of ordinary skill in the art will appreciate that an suitable mechanism may be used to apply compressive force to P/N-type ingot 200. In particular embodiments, after adhesive 204 has hardened, a P/N-type block 202 may be sliced away from P/N-type ingot 200 as explained in more detail with respect to FIG. 3.

FIG. 3 illustrates an example view of P/N-type block 206 after being separated from P/N-type ingot 200. P/N-type block 206 includes a plurality of N-type layers 208a and P-type layers 208b, each layer 208 being connected to the next along bond line 205 by adhesive 204. P/N-type block 206 may be cut to any shape or size and may include any suitable number of layers 208, though a typical block 206 may be approximately 6 millimeters (“mm”) long (as measured parallel to layers 208), 6 mm wide (as measured perpendicular to layers 208), and 2.5 mm thick. A typical P/N-type block 206 having these dimensions may include approximately 20 layers 208.

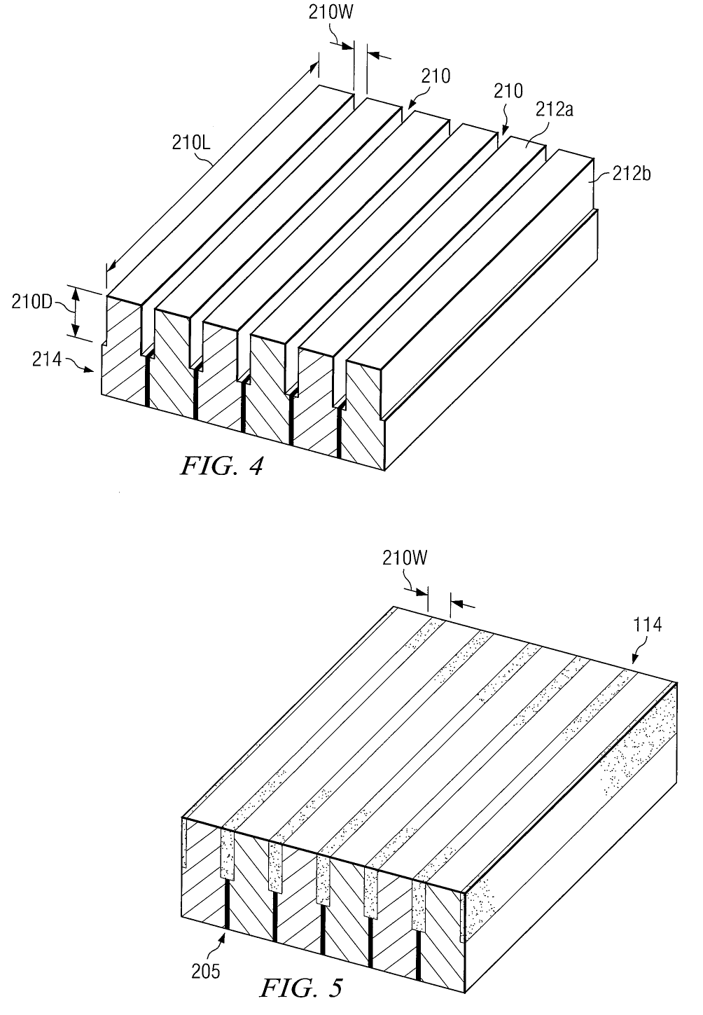

Depending upon the design of P/N-type block 206 and the thermoelectric material used to form layers 208, layers 208 may be oriented in block 206 such that the direction of current flow, as ultimately applied to the elements 104 of P/N-type array 102, coincides with the direction of optimal thermoelectric performance of the thermoelectric material. In particular embodiments, after separating P/N-type block 206 from P/N-type ingot 200, a plurality of channels 210 may be created in P/N-type block 206 as explained in more detail with respect to FIG. 4.

FIG. 4 illustrates an example view of a plurality of channels 210 that have been formed in P/N-type block 206. In particular embodiments, channels 210 may be formed in P/N-type block 206 after adhesive 204 has hardened so that adhesive 204 holds layers 208 still relative to one another during creation of channels 210. In particular embodiments, channels 210 may traverse the entire length of P/N-type block 206 and may be formed along each of bond lines 205 such that channels 210 run parallel to layers 208.

In particular embodiments, the process of creating a channel 210 may remove a portion of each of the adjacent layers 208 to channel 210 as well as the adhesive 204 holding the adjacent layers 208 together along their bond line 205. As an example and not by way of limitation, each channel 210 may remove all of the adhesive 204 disposed along its path as well as an approximately equal amount of the adjacent layers 208. Each channel 210 may be defined by a channel depth 210D, a channel width 210W, and a channel length 210L. For example, in a typical configuration for channel 210, channel width 210W may be 0.1 mm wide, channel depth 210D may be 1 mm deep, and channel length 210L may be coextensive with the length of P/N-type block 206 as measured parallel to layers 208. In particular embodiments, channel width 210W may be less than the width of the layers 208 in P/N-type block 206. Depending upon design, each of channels 210 may be approximately uniform to one another in dimension (e.g., length, width, and depth) taking into account minor variations in size due to imperfections in the process of creating channels 210.

As a consequence of creating channels 210 in P/N-type block 206, a series of N-type fins 212a and P-type fins 212b will be created in P/N-type block 206. In particular embodiments, the channel depth 210D may not extend all the way through P/N-type block 206, leaving an uncut bottom 214 on P/N-type block 206. In an example situation, uncut bottom may be approximately 1.5 mm thick after channels 210 are formed. Uncut bottom 214 may serve the purpose of connecting P-type fins 212b and N-type fins 212a together during further manufacturing steps. P-type fins 212b and N-type fins 212a may respectively represent the portion of N-type layers 208a and P-type layers 208b extending out of uncut bottom 214 after channels 210 have been formed. Depending upon the design of channels 210, the length, width, or height of each fin in P/N-type block 206 may be approximately uniform taking into account minor variations in size due to imperfections in the process of creating channels 210. As an example and not by way of limitation, a fin 212 may be approximately 0.2 mm wide, 6 mm long, and 1 mm tall. One of ordinary skill in the art will appreciate that the present disclosure contemplates any suitable number and configuration of P-type fins 212b and N-type fins 212a being connected by an uncut bottom 214 of any suitable thickness.

Depending upon the method of manufacture, channels 210 may be formed by any method or device capable of creating an approximately uniform channel of space between adjacent layers 208. As an example and not by way of limitation, channels 210 may be formed using diamond dicing saws, wire saws, acid saws, wire edm, RAM edm, or laser cutting. One of ordinary skill in the art will appreciate that the above-described embodiments of channels 210 were presented for the sake of explanatory simplicity and will further appreciate that the present disclosure contemplates the use of any suitable mechanism or method to create channels 210 in P/N-type block 206. In particular embodiments, after channels 210 have been created in P/N-type block 206, channels 210 may be filled with an electrically and thermally insulating material 114 as explained in more detail with respect to FIG. 5.

FIG. 5 illustrates a view of P/N-type block 206 wherein channels 210 have been backfilled with an electrically and thermally insulating material 114. Electrically and thermally insulating material 114 may be any formula or compound capable of forming a rigid, electrically and thermally insulating bond between P-type fins 212b and N-type fins 212a. As an example and not by way of limitation, electrically and thermally insulating material 114 may be Stycast W19, Stycast 1266, Loctite Hysol FP4531, or other epoxy or liquid adhesive. Electrically and thermally insulating material 114 may be the same as or different from adhesive 204. One of ordinary skill in the art will appreciate that the above-described embodiments of electrically and thermally insulating material 114 were presented for the sake of explanatory simplicity and will further appreciate that the present disclosure contemplates the use of any suitable adhesive 204 to form a rigid, electrically and thermally insulating bond between P-type fins 212b and N-type fins 212a.

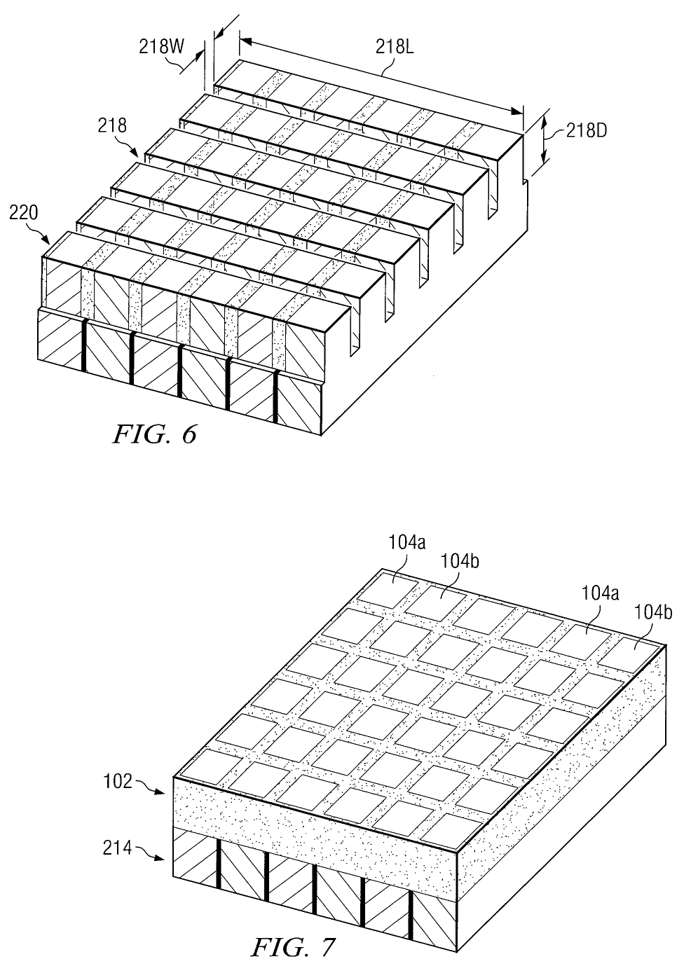

As can be see in the illustrated embodiment, channel width 210W may be greater than the width of the original bond lines 205 between layers 208. Thus, by adjusting channel width 210W, a manufacturer may account for any irregularities along bond line 205 and ensure that the spacing between fins 212 is uniform. In particular embodiments, after electrically and thermally insulating material 114 has cured (e.g., hardened) in channels 210, a plurality of transverse channels 218 may be created in P/N-type block 206 as explained in more detail with respect to FIG. 6.

FIG. 6 illustrates an example view of a plurality of transverse channels 218 that have been formed in P/N-type block 206. In particular embodiments, electrically and thermally insulating material 114 may be allowed to harden before channels 218 are formed so that electrically and thermally insulating material 114 will not leak into transverse channels 218 or otherwise deform during the creation of transverse channels 218. Furthermore, after electrically and thermally insulating material 114 has hardened, it may stabilize P-type fins 212b and N-type fins 212a during the creation of transverse channels 218. In particular embodiments, transverse channels 218 may traverse the entire width of P/N-type block 206 and may be formed perpendicular to channels 210. Each transverse channel 218 may be defined by a transverse channel depth 218D, a transverse channel width 218W, and a transverse channel length 218L.

Typically, each of transverse channels 218 are approximately uniform to one another in dimension (e.g., length, width, and depth) and extend only a portion of the way though P/N-type block 206, leaving uncut portion 214 intact. Furthermore, transverse channels 218 may be similar to channels 210 in dimension. That is, transverse channel depth 218D may be equal to channel depth 210D, transverse channel width 218W may be equal to channel width 210W, and transverse channel length 218L may be equal to channel length 210L (insofar as P/N-type block 206 is square). However, the present disclosure also contemplates embodiments where one or more dimensions of transverse channels 218 differ from channels 210. For example, if the length of P/N-type block 206 differs from the width of P/N-type block 206, the channel length 210L may differ from transverse channel length 218L.

As a consequence of creating transverse channels 218 in P/N-type block 206, a series of P/N-type fins 220 will be created in P/N-type block 206. In particular embodiments, the length, width, and height of each P/N-type fin 218 in P/N-type block 206 may be uniform. As an example and not by way of limitation, a fin 218 may be approximately 0.2 mm wide, 6 mm long (as measured perpendicular to layers 208), and 1 mm tall. Assuming that transverse channels 218 do not extend all the way through P/N-type block 206, uncut bottom 214 will be left intact to connect P/N-type fins 220 together during further manufacturing steps. Since P/N-type fins 220 may run transverse to fins 212, P/N-type fins 220 may contain alternating bands of P-type material, N-type material, and electrically and thermally insulating material 114.

One of ordinary skill in the art will appreciate that the dimensions of channels 210 and transverse channels 218 may ultimately affect the size of the TE elements 104. For example, channel depth 210D and transverse channel depth 218D may correspond to a height of TE elements 104, while channel width 210W and transverse channel width 218W may correspond to the spacing between TE elements 104. Likewise the orientation of transverse channels 218 relative to channels 210D may affect the cross-sectional shape of TE-elements 104. Accordingly, one of ordinary skill in the art will further appreciate that the present disclosure contemplates creating TE-elements 104 of any desired shape and size, having any desired spacing, by varying the dimensions of channels 210 and transverse channels 218 and by varying the orientation of transverse channels 218 relative to channels 210.

Depending upon the method of manufacture, transverse channels 218 may be formed by the same or different mechanisms or methods as those described with respect channels 210, although one of ordinary skill in the art will appreciate that any suitable mechanism or method may be used to create transverse channels 218 in P/N-type block 206. In particular embodiments, after transverse channels 218 have been created in P/N-type block 206, transverse channels 218 may be filled with electrically and thermally insulating material 114 as explained in more detail with respect to FIG. 7.

FIG. 7 illustrates a view of P/N-type block 206 wherein transverse channels 218 have been backfilled with electrically and thermally insulating material 114. In particular embodiments, the portion of P/N-type block 206 disposed on top of uncut bottom 214 may include an evenly spaced array 102 of N-type elements 104a and P-type elements 104b separated from one another by lines of electrically and thermally insulating material 114. In particular embodiments, after electrically and thermally insulating material 114 has cured (e.g., hardened) in channels 218, uncut bottom 214 may be removed from array 102 as explained in more detail with respect to FIG. 8.

FIG. 8 illustrates an example view of uncut bottom 214 being removed from array 102. In particular embodiments, uncut bottom 214 and any other excess or undesired material may be removed from array 102, for example, by lapping, slicing, grinding, or other suitable means. As an example, after electrically and thermally insulating material 114 has hardened, the top and bottom of array 102 may be ground down to adjust the length of the elements 104 in array 102 and to produce flat faces on array 102 suitable for applying electrical interconnects 224 to elements 104.

In particular embodiments, array 102 may be trimmed to contain a desired number of TE elements 104 or to have a certain shape. Although array 102 may be trimmed to any desired configuration containing any desired number of elements, an example array 102 may include approximately 400 TE elements, each TE element having an exposed face of approximately 0.04 mm² and each TE element 104 being approximately 0.5 mm tall. Each TE element 104 could be separated from the next by a line of electrically and thermally insulating material 114 that is approximately 0.1 mm wide.

In particular embodiments, the N-type elements 104a and P-type elements 104b contained in array 102 may have identical dimensions to one another and the lines of electrically and thermally insulating material 114 running between elements 104 may uniformly separate elements 104 from one another. One of ordinary skill in the art will appreciate that numerous configurations of array 102 are possible through various embodiments of the method described herein. In particular embodiments, once array 102 has been separated from uncut bottom 214, diffusion barriers and electrical interconnects 224 may be applied to array 102 as explained in more detail with respect to FIG. 9.

FIG. 9 illustrates an example embodiment of array 102 after diffusion barriers and electrical interconnects 224 have been applied to array 102. In particular embodiments, patterning methods such as photolithography or shadow mask techniques combined with metal deposition techniques such as sputtering, plating or other suitable metallization technique may be used to create electrical interconnects 224 on N-type elements 104a and P-type elements 104b, though one of ordinary skill in the art will appreciate that the present disclosure contemplates using any suitable method to apply diffusion barriers and electrical interconnects 224 to array 102.

Once the electrical interconnects 224 have been applied to array 102, dielectric coverings such as ceramic plates, flexible sheets, or protective coatings such as a PARYLENE (e.g., PARYLENE HT) may be attached to array 102. In particular embodiments, electrical interconnects 224 may be attached to array 102 as part of a patterned metallization deposited on the thermoelectric coverings rather than being applied directly to array 102. In this case, array 102 may be coupled to electrical interconnects 224 on the dielectric coverings, for example, by solder or electrically conductive epoxy. In particular embodiments, array 102 may include enough individual elements 104 and have a large enough surface area to support multiple thermoelectric circuits per array 102. After being formed on array 102, these thermoelectric circuits may then be diced apart to form multiple thermoelectric devices 100.

FIG. 10 illustrates example steps in a method for manufacturing array 102 in accordance with an example embodiment of the present disclosure. The method begins at step 300 where an ingot of P-type material and an ingot of N-type material are provided. In step 302, the ingot of P-type material and the ingot N-type material are sliced into N-type wafers 202a and P-type wafers 202b, respectively. In step 304, an adhesive 204 is applied to at least one side of each wafer 202. In step 306, N-type wafers 202a and P-type wafers 202b are alternatingly stacked into P/N-type ingot 200 and are pressed together to minimize bond lines 205. Furthermore, any excess adhesive 204 that is squeezed out of bond lines 205 may be scraped away. In step 308, adhesive 204 is allowed to cure. In step 310, a P/N-type block 206 is sliced from the P/N-type ingot. In step 312, a series of channels 210 are cut along the bond lines 205 that separate each wafer 202 in P/N-type block 206, creating a series of P-type fins 212b and N-type fins 212a connected by an uncut bottom 214. In step 314, an electrically and thermally insulating material 114 is applied in the channels 210 between the P-type fins 212b and N-type fins 212a. In step 316, the electrically and thermally insulating material 114 is allowed to cure. In step 318, a series of transverse channels 218 are cut perpendicular to channels 210 in the P/N-type block 206, creating a series of P/N-type fins 220. Since the transverse channels 218 are cut across bond lines 205, each P/N-type fin 220 contains alternating bands of P-type material and N-type material. In step 320, an electrically and thermally insulating material 114 is backfilled in transverse channels 218. In step 322, electrically and thermally insulating material 114 is allowed to cure. In step 324, uncut bottom 214 and any other excess material on P/N-type block 206 may be lapped, sliced, or ground away from the P/N-type block 206, leaving a single, solid array 102 of N-type elements 104a and P-type elements 104b bonded together by lines of electrically and thermally insulating material 114. In step 326 diffusions barriers and electrical interconnects 224 are applied to the array 102.

Although the present disclosure has been described in several embodiments, a myriad of changes, substitutions, and modifications may be suggested to one skilled in the art, and it is intended that the present disclosure encompass such changes, substitutions, and modifications as fall within the scope of the present appended example claim(s). Moreover, none of the methodology described herein should be construed as a limitation on the order of events insofar as one of skill in the art would appreciate that such events could be altered without departing from the scope of the disclosure.

What is claimed is:

1. A method for creating an array of thermoelectric elements, comprising:
providing a rigid block including P-type material layers and N-type material layers stacked in an alternating relationship and bonded together by an adhesive;
forming first channels in the block parallel to the P-type material layers and the N-type material layers, the first channels partially extending through a depth of the block leaving an uncut bottom on the block;
filling the first channels with an electrically and thermally insulating material;
forming second channels in the block transverse to the first channels, the second channels partially extending through the depth of the block;
filling the second channels with the electrically and thermally insulating material; and
removing the uncut bottom from the block.

2. The method of claim 1, wherein providing a rigid block comprises:
providing P-type wafers and N-type wafers;
applying the adhesive to the P-type wafers and N-type wafers;
stacking the P-type wafers and N-type wafers in an alternating relationship;
pressing the P-type wafers and N-type wafers together to decrease widths of the bond lines between the P-type wafers and N-type wafers;
curing the adhesive to form a P/N-type ingot;
cutting the rigid block from the P/N-type ingot.

3. The method of claim 2, further comprising, before curing the adhesive, removing any excess adhesive that is squeezed out of the bond lines when the P-type and N-type wafers are pressed together.

4. The method of claim 1, wherein slicing the first channels in the block parallel to the P-type material layers and the N-type material layers comprises slicing the first channels between the P-type material layers and the N-type material layers.

5. The method of claim 1, wherein removing the uncut bottom from the block comprises:
forming a P/N-type array by removing the uncut bottom from the block, the P/N-type array comprising P-type elements and N-type elements separated by lines of the electrically and thermally insulating material.

6. The method of claim 5, further comprising applying electrical interconnects to the P/N-type array, the electrical interconnects electrically coupling at least one P-type element to at least one N-type element.

7. The method of claim 5, further comprising trimming the array to include a desired number of the P-type elements and N-type elements.

8. The method of claim 5, wherein each element of the P-type elements and N-type elements is approximately uniform in dimension to every other element of the P-type elements and N-type elements.

9. The method of claim 1, wherein:
each channel of the first channels is approximately uniform in dimension to every other channel of the first channels; and
each channel of the second channels is approximately uniform in dimension to every other channel of the second channels.

10. The method of claim 1, wherein:
the first channels traverse a length of the block, the length measured parallel to the P-type material layers and N-type material layers;
the second channels traverse a width of the block, the width measured perpendicular to the P-type material layers and N-type material layers;
the first channels intersect the second channels; and
a depth of the first channels is equal to a depth of the second channels.

11. The method of claim 1, wherein:
the first channels are sliced along bond lines between the P-type material layers and N-type material layers, the channels forming N-type fins and P-type fins; and
the first channels are sliced such that a width of each fin of the N-type fins and P-type fins approximately matches a width of every other fin of the N-type fins and P-type fins.

12. The method of claim 11, wherein the first channels remove the adhesive from between the N-type fins and the P-type fins.

13. The method of claim 1, wherein:
the second channels form P/N-type fins comprising both P-type material and N-type material; and
the second channels are sliced such that a width of each fin of the P/N-type fins matches a width of every other fin of the P/N-type fins.

14. The method of claim 1, wherein each of the first channels is defined by a P-type material layer on a first side and an N-type material layer on a second side and the uncut bottom on a third side.

15. The method of claim 1, wherein the first channels are perpendicular to the second channels.

16. A method for creating an array of thermoelectric elements, comprising:
providing P-type wafers and N-type wafers;
applying the adhesive to the P-type wafers and N-type wafers;
stacking the P-type wafers and N-type wafers in an alternating relationship;
pressing the P-type wafers and N-type wafers together to decrease widths of the bond lines between the P-type wafers and N-type wafers;
curing the adhesive to form a P/N-type ingot;
cutting a rigid block from the P/N-type ingot including P-type material layers and N-type material layers stacked in an alternating relationship and bonded together by the adhesive; and
creating an array P-type elements and N-type elements from the rigid block.

17. The method of claim 16, further comprising, before curing the adhesive, removing any excess adhesive that is squeezed out of the bond lines when the P-type and N-type wafers are pressed together.

18. The method of claim 16, wherein each element of the P-type elements and N-type elements is approximately uniform in dimension to every other element of the P-type elements and N-type elements.

19. The method of claim 16, comprising pressing the P-type wafers and the N-type wafers together until the P-type wafers and the N-type wafers touch one another along the bond lines.

20. A method for creating an array of thermoelectric elements, comprising:
first, providing a rigid block including P-type material layers and N-type material layers stacked in an alternating relationship and bonded together by an adhesive;
second, forming first channels in the block parallel to the P-type material layers and the N-type material layers, the first channels partially extending through a depth of the block leaving an uncut bottom on the block;
third, filling the first channels with an electrically and thermally insulating material;
fourth, curing the electrically and thermally insulating material applied in the third step;
fifth, forming second channels in the block transverse to the first channels, the second channels partially extending through the depth of the block;
sixth, filling the second channels with the electrically and thermally insulating material;
seventh curing the electrically and thermally insulating material applied in the sixth step; and
eighth, removing the uncut bottom from the block, wherein the steps are performed in the order in which they are numbered.
